(19) United States
(12) Patent Application Publication
(10) Pub. No.: US 2001/0048704 A1
(43) Pub. Date: Dec. 6, 2001

(54) Distributed feedback laser diode

(75) Inventor: Manabu Matsuda, Kawasaki (JP)

Correspondence Address: ARMSTRONG,WESTERMAN, HATTORI,, MCLELAND & NAUGHTON, LLP, 1725 K STREET, NW, SUITE 1000, WASHINGTON, DC, 20006, US

(73) Assignee: Fujitsu Limited, Kawasaki (JP)

(21) Appl. No.: 09/816,371

(22) Filed: Mar. 26, 2001

(30) Foreign Application Priority Data
Jun. 2, 2000 (JP) 2000-166321

(51) Int. Cl. H01S 5/00

(52) U.S. Cl. 372/43

(57) ABSTRACT

By setting a width of an active layer larger than a cut-off width of a higher-order transverse mode in a distributed feedback (DFB) laser diode, laser emission in the higher-order transverse mode is restrained as well as a unevenness in an emission wavelength caused by a unevenness in the active layer can be minimized.

### BACKGROUND OF THE INVENTION

1. Field of the Invention

The present invention generally relates to an optical semiconductor device. More particularly, the present invention relates to a distributed feedback laser diode.

2. Description of the Related Art

A distributed feedback (DFB) laser diode is a laser diode having a diffraction grating formed in an active area, and utilizing the diffraction grating as an optical resonator. Such a DFB laser diode is applied in wide areas relating to a wavelength division multiplex (WDM) optical communication technology. The WDM optical communication technology transmits information through a plurality of channels having different wavelengths by using a number of light sources with different wavelengths. A wavelength of each channel is strictly determined. In addition, a wavelength difference between adjacent channels is very narrow, for instance, 0.8 nm or 0.4 nm, and, thus, each light source is required to emit light of an extremely stable wavelength.

Historically, laser diodes have developed from a Fabry-Perot laser diode, which includes a Fabry-Perot resonator, i.e., an optical resonator formed by a pair of cleaved facets. The Fabry-Perot laser diode emits light by amplifying a ray reflecting back and forth between the pair of cleaved facets by stimulated emission.

If a width of the optical resonator included in the Fabry-Perot laser diode is large, a higher-order transverse mode appears in the optical resonator. In a case in which a light intensity in the higher-order transverse mode exceeds a threshold of laser emission, emission starts in the higher-order transverse mode in addition to a desired vertical mode. To prevent the emission in the higher-order transverse mode, the Fabry-Perot laser diode forms the optical resonator to have a width of 1.3-1.6 μm that can cut off the higher-order transverse mode. Such a design of limiting a width of an optical resonator in a laser diode to 1.3-1.6 μm is applied not only to a design of the Fabry-Perot laser diode, but also to a design of a DFB laser diode.

FIG. 1 is a diagram showing a structure of a related-art DFB laser diode 10. The related-art DFB laser diode 10 is formed on an n-type InP substrate 11 that serves also as a cladding layer, and includes a non-dope GaInAsP optical waveguide layer 12 formed on the InP substrate 11, and a non-dope GaInAsP active layer 13 formed on the optical waveguide layer 12. A diffraction grating 12A is formed at an interface between the optical waveguide layer 12 and the substrate 11. The substrate 11, the optical waveguide layer 12 and the active layer 13 are processed through wet etching. As a result, a mesa structure existing in an axial direction of the laser diode 10 is formed on the top of the substrate 11, the mesa structure including the optical waveguide layer 12 and the active layer 13.

Additionally, a p-type InP buried layer 14 is formed at both sides of the mesa structure on the substrate 11. Furthermore, an n-type InP current blocking layer 15 is formed at both sides of the active layer 13 on the top of the buried layer 14 so that the active layer 13 can be exposed. A p-type InP upper cladding layer 16 is formed on the top of the current blocking layer 15 so that the upper cladding layer 16 can cover the exposed active layer 13. A p-type GaInAsP contact layer 17 is formed on the top of the upper cladding layer 16.

Additionally, an insulating film 18 is formed on the top of the contact layer 17, the insulating film 18 having an opening part existing in the axial direction corresponding to an mesa area including the optical waveguide layer 12 and the active layer 13. An upper electrode 19A is formed on the insulating film 18. A lower electrode 19B is formed on a lower surface of the substrate 11.

In a case of using the DFB laser diode 10 shown in FIG. 1 in the WDM optical communication technology, the DFB laser diode 10 is required to emit light of an extremely stable wavelength. An emission wavelength of the DFB laser diode 10 is determined by an effective length of an optical resonator included therein. The effective length of the optical resonator is basically determined by a pitch of a diffraction grating formed in an active area. Light emission that is carried through the optical waveguide layer 12 as well as interacts with the diffraction grating 12A enters to the buried layer 14 and the current blocking layer 15 that are adjacent to the optical waveguide layer 12, at some degree. As a result, the effective length of the optical resonator is affected by a refractive index of adjacent InP layers. If a width of the mesa area is narrower, an influence from the adjacent InP layers on the effective length of the optical resonator increases. On the other hand, if the width of the mesa area is wider, the influence from the adjacent InP layers on the effective length of the optical resonator decreases. However, there is a limit to accurately control the width of the mesa area, since the mesa area is generally formed by a wet-etching method using a mask.

Accordingly, in a case in which the width of the mesa area is narrower in the DFB laser diode 10 shown in FIG. 1, an error in the effective length of the optical resonator increases, the error being caused by a patterning error. Consequently, an emission wavelength becomes different from a designed wavelength. FIG. 2 is a diagram showing a difference between an emission wavelength and a designed wavelength in a case of changing a width of an active layer included in the DFB laser diode 10 shown in FIG. 1. In details, FIG. 2 shows a difference between a designed emission wavelength and an actual emission wavelength at various widths of an active layer (the mesa area) of the DFB laser diode 10 when each width of the active layer changes by 0.1 μm.

As shown in FIG. 2, the difference between the designed emission wavelength and the actual emission wavelength becomes more apparent as the width of the active layer decreases. Particularly, the difference of more than 1.0 nm occurs in a case in which the width of the active layer is less than or equal to 1.0 μm. As described above, an error tends to occur easily between the actual emission wavelength and the designed emission wavelength at a DFB laser diode such as the DFB laser diode 10 following the design of the Fabry-Perot laser diode. Consequently, a production yield of laser diodes decreases by such an error.

### SUMMARY OF THE INVENTION

Accordingly, it is a general object of the present invention to provide a distributed feedback laser diode, in which the disadvantages described above are eliminated. A more particular object of the present invention is to provide a distributed feedback laser diode having a structure suitable for minimizing a difference between a designed emission wavelength and an actual emission wavelength.

The above-described object of the present invention is achieved by a distributed feedback laser diode, including a substrate having a first conduction type; a mesa structure having a projecting part thereof extended in an axial direction on the substrate, and forming a lower cladding layer; an active layer formed on the projecting part, and having a width thereof wider than a cut-off width of a higher-order transverse mode formed in the active layer; a diffraction grating optically combined with the active layer on the projecting part; an upper cladding layer formed on the active layer, and having a second conduction type; a first electrode electrically connected to the upper cladding layer; and a second electrode electrically connected to the substrate.

By setting a width of the active layer larger than the cut-off width of the higher-order transverse mode in the distributed feedback (DFB) laser diode, laser emission in the higher-order transverse mode is restrained as well as a unevenness in an emission wavelength caused by a unevenness in the active layer can be minimized. Accordingly, the difference between the emission wavelength and the designed emission wavelength can be minimized.

Other objects, features and advantages of the present invention will become more apparent from the following detailed description when read in conjunction with the accompanying drawings.

### BRIEF DESCRIPTION OF THE DRAWINGS

FIG. 1 is a diagram showing a structure of a related-art DFB laser diode;

FIG. 2 is a diagram showing a difference between an emission wavelength and a designed wavelength in a case of changing a width of an active layer included in the DFB laser diode shown in FIG. 1;

FIGS. 3A and 3B are a squint diagram and a cross sectional diagram, respectively, showing a distributed feedback (DFB) laser diode, according to a first embodiment of the present invention;

FIGS. 4A, 4B and 4C are diagrams showing light intensity distributions in various higher-order transverse modes occurring at the DFB laser diode;

FIGS. 5A and 5B are diagrams showing cutoff widths for the higher-order transverse modes;

FIG. 6 is a squint diagram showing a structure of a DFB laser diode, according to a second embodiment of the present invention;

FIGS. 7A, 7B and 7C are diagrams showing a manufacturing process of the DFB laser diode shown in FIG. 6;

FIGS. 8A, 8B and 8C are diagrams showing the manufacturing process of the DFB laser diode shown in FIG. 6;

FIGS. 9A and 9B are diagrams showing the manufacturing process of the DFB laser diode shown in FIG. 6;

FIG. 10 is a squint diagram showing a structure of a ridge waveguide DFB laser diode, according to a third embodiment of the present invention; and

FIG. 11 is a diagram showing a DFB laser diode, according to a fourth embodiment of the present invention.

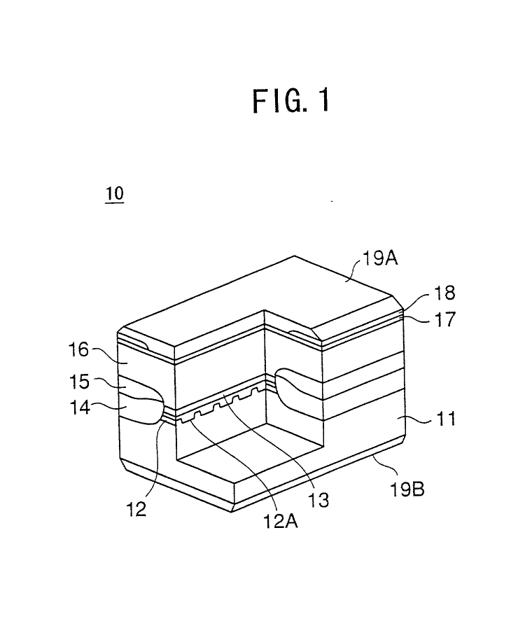

### DESCRIPTION OF THE PREFERRED EMBODIMENTS

A description will now be given of preferred embodiments of the present invention, with reference to the accompanying drawings.

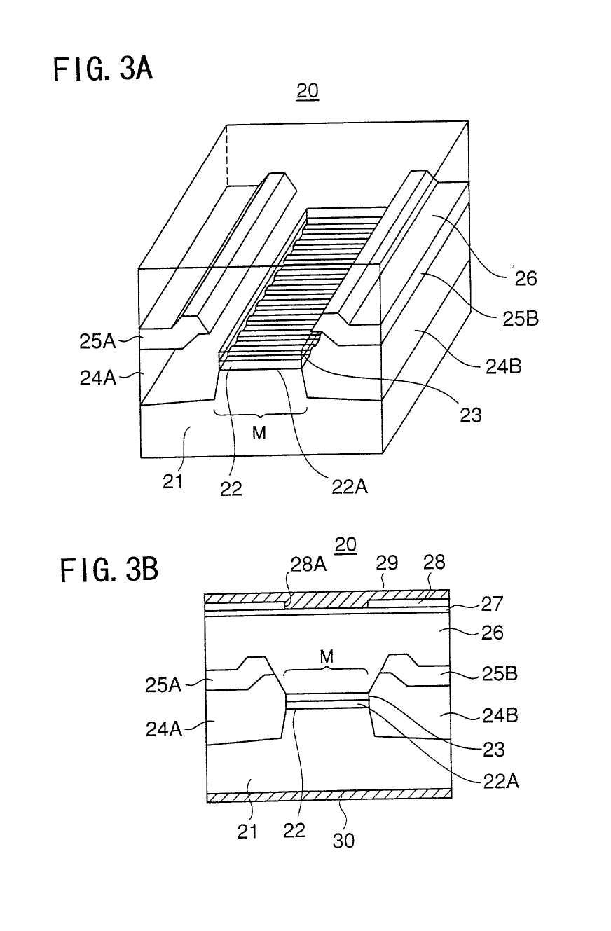

FIGS. 3A and 3B are a squint diagram and a cross sectional diagram showing a distributed feedback (DFB) laser diode 20, according to a first embodiment of the present invention. The DFB laser diode shown in FIGS. 3A and 3B includes a substrate 21, an optical waveguide layer 22, a diffraction grating 22A, an active layer 23, buried layers 24A and 24B, current blocking layers 25A and 25B, an upper cladding layer 26, a contact layer 27, a SiO₂ film 28, an opening part 28A, an upper electrode 29 and a lower electrode 30.

The DFB laser diode 20 is formed on the n-type InP substrate 21 including a mesa structure M existing in an axial direction of the DFB laser diode. The diffraction grating 22A having a depth of 30 nm in the axial direction and a 242 nm cycle, is formed in the substrate 11 along with the mesa structure M. The GaInAsP optical waveguide layer 22 having a band-gap wavelength of 1200 nm is formed on the top of the mesa structure M approximately for 120 nm. The GaInAsP active layer 23 having a bandgap wavelength of 1550 nm is formed on the top of the optical waveguide layer 22 approximately for 120 nm so that the mesa structure M functions as a lower cladding layer against the active layer 23.

Additionally, the p-type InP buried layers 24A and 24B are formed respectively on one side and the other side of the mesa structure M so that the buried layers 24A and 24B contact both sides (wall surfaces) of the optical waveguide layer 22 and of the active layer 23 located on the top of the optical waveguide layer 22. The n-type InP current blocking layers 25A and 25B are formed respectively on the top of the buried layers 24A and 24B. The buried layers 24A and 24B, and the current blocking layers 25A and 25B are formed so that the active layer 23 is exposed. Additionally, the p-type InP upper cladding layer 26 is formed on the top of the current blocking layers 25A and 25B so as to cover the exposed active layer 23.

Additionally, the p-type GaInAsP contact layer 27 is formed on the top of the upper cladding layer 26. The SiO₂ film 28 is formed on the top of the contact layer 27 so that the SiO₂ film 28 includes the opening part 28A at its center for the upper electrode 29 formed on the top of the SiO₂ film 28 to contact the contact layer 27 through the opening part 28A. The lower electrode 30 is formed on the main bottom surface of the substrate 21. Additionally, the DFB laser diode 20 shown in FIGS. 3A and 3B includes reflection-protecting films not shown in the figures on both side facets thereof.

In the DFB laser diode 20 shown in FIGS. 3A and 3B, emission light created by stimulated emission in the active layer 23 is diffracted by the diffraction grating 22A while being guided through the optical waveguide layer 22. A standing wave formed as a result is amplified by the stimulated emission, and, thus, an optical distributed feedback occurs. When an intensity of the emission light exceeds a threshold, laser emission occurs. In such a DFB laser diode 20, the active layer 23, the optical waveguide layer 22 and the diffraction grating 22A form main parts of the optical resonator include in the DFB laser diode 20.

According to the first embodiment, a width of an active area (the active layer 23), that is, a width of the mesa structure M, is set larger than that of a related-art DFB laser diode so as to reduce an influence of an error caused by formation of the mesa structure M on an emission wavelength. For instance, setting the width of the active layer 23 to a width equal to or higher than 3.0-4.0 μm can control an error in the emission wavelength to about 0.1 μm or the less in a case in which the width of the active layer 23 alters by 0.1 μm.

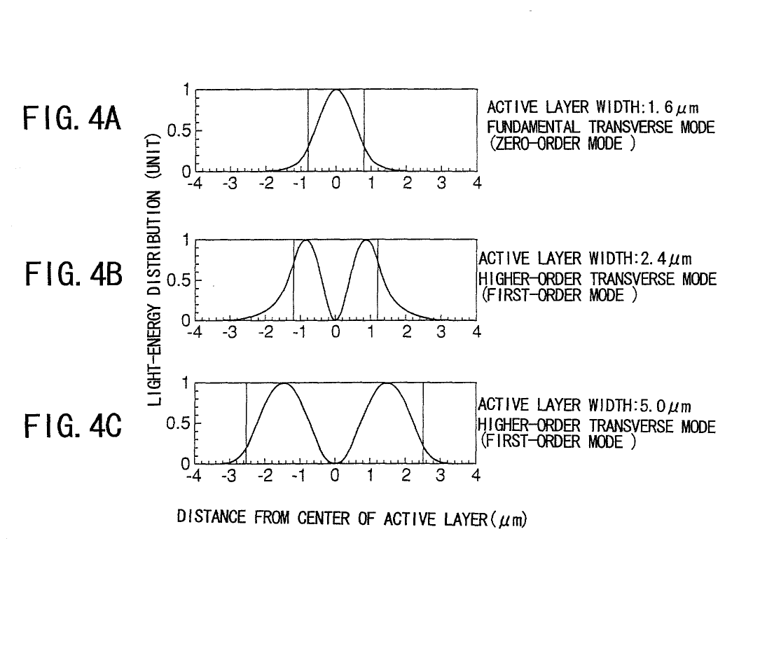

The standing wave formed as described above in the optical resonator includes various higher-order modes in addition to a fundamental mode. Such higher-order transverse modes should be considered especially in the DFB laser diode 20 according to the present invention, for setting the width of the active layer 23 wider. FIGS. 4A, 4B and 4C are diagrams showing light intensity distributions in various higher-order transverse modes occurring at the DFB laser diode 20. The same higher-order transverse modes occur at a related-art Fabry-Perot laser diode.

In a case in which the width of the active layer 23 is small, for instance, 1.6 μm, a transverse mode occurring in the optical resonator can only be the fundamental mode (a zero-order mode). A maximum light intensity or a maximum light energy can be obtained at the center of the optical resonator, as shown in FIG. 4A. As described above, a width of an active layer in a related-art Fabry-Perot laser diode is designed to be small so that only a fundamental transverse mode occurs in its optical resonator.

On the other hand, by increasing the width of the active layer 23 to 2.4 μm as shown in FIG. 4B, or to 5.0 μm as shown in FIG. 4C, the light intensity becomes zero at the center of axis in the optical resonator. Additionally, a first-order transverse mode appears, in which the maximum light intensity is located on the left and right sides of the center of the active layer 23. If the light intensity exceeds a threshold of laser emission in such a higher-order (first-order) transverse mode, a laser diode emits light in the higher-order transverse mode whether the laser diode is a Fabry-Perot laser diode or a DFB laser diode.

Especially, in the Fabry-Perot laser diode, an optical positive feedback is caused by a pair of cleaved facets forming an optical resonator, and, thus, the optical positive feedback is affected by a part of the light energy distributed outside an active layer, the light energy being created in the higher-order transverse mode shown in FIGS. 4B and 4C. Accordingly, emission tends to occur especially in the higher-order mode, in the Fabry-Perot laser diode.

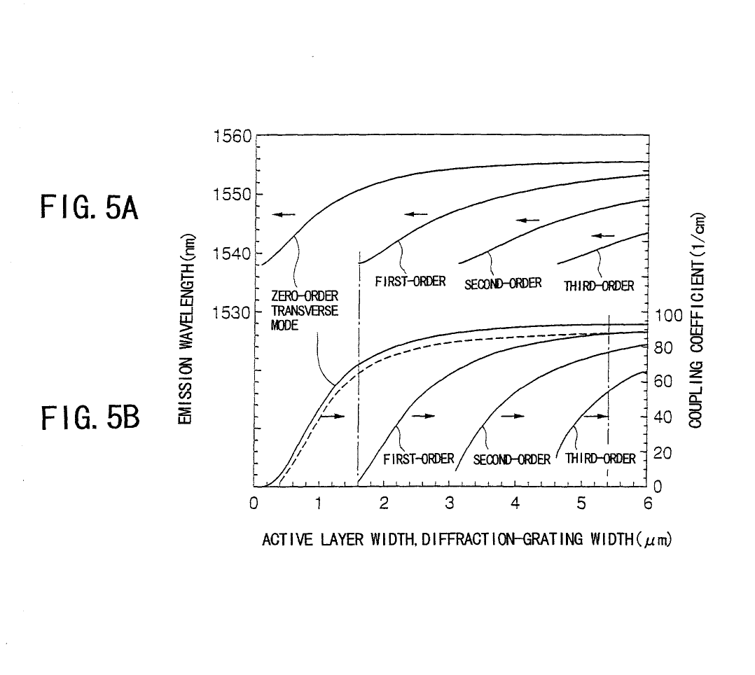

On the other hand, in the above-described higher-order mode, a light intensity distribution spreads to an area that is located outside the active layer, and that has a low effective refraction index of a medium. Accordingly, a waveguide effect of the light energy decreases. FIG. 5A is a diagram showing a width of an active layer (a cut-off width) at which a higher-order transverse mode becomes unable to be wave-guided because of a decrease in an effective refraction index in an optical resonator. It should be noted that the cutoff width is a function of an emission wavelength, and a relation between the emission wavelength and the cut-off width shown in FIG. 5A is valid for both of a Fabry-Perot laser diode and a DFB laser diode including the DFB laser diode 10 and 20.

As shown in FIG. 5A, a width of the active layer at which the first-order transverse mode becomes unable to be wave-guided is about 1.6 μm, in a laser diode emitting light of an emission wavelength 1550 nm. Therefore, a width of the active layer or a width of the mesa structure is set to 1.3-1.6 μm to cut off higher-order transverse modes including the first-order transverse mode, in the related-art Fabry-Perot laser diode, since emission in a higher-order mode easily occurs in the related-art Fabry-Perot laser diode because of reflection from a cleaved facet forming its optical resonator.

An inventor of the present invention, by focusing on a fact that an optical positive feedback is generated by a diffraction grating and not by a cleaved facet in a DFB laser diode, discovered a case in which emission in a higher-order transverse mode can be prevented even if a width of the active layer is set larger than the cut-off width.

As describe above with reference to FIGS. 4A and 4B, an actual light intensity distribution exists also in an area outside the active layer, in the higher-order transverse mode. Additionally, in the Fabry-Perot laser diode, light energy distributed outside the active layer affects the optical positive feedback causing the laser emission. On the other hand, in the DFB laser diode, the diffraction grating causing the optical positive feedback is limited within the width of the active layer, and the light energy distributed outside the active layer does not affect the optical positive feedback. Additionally, as shown in the light intensity distributions shown in FIGS. 4B and 4C, the light intensity distribution is zero at the center of axis in the width of the active layer. Thus, in the DFB laser diode, a boding coefficient decreases sharply as a transverse mode shifts from the fundamental mode to the higher-order modes at a single active layer width.

A relation shown in FIG. 5B indicates that a threshold of laser emission increases in the higher-order transverse modes at the DFB laser diode. Accordingly, there is a case in which emission in the higher-order modes are prevented even if a width of the active layer 23 or a width of the mesa structure M is set larger than the cut-off width shown in FIG. 5A (a mode cut-off width) in the DFB laser diode 20.

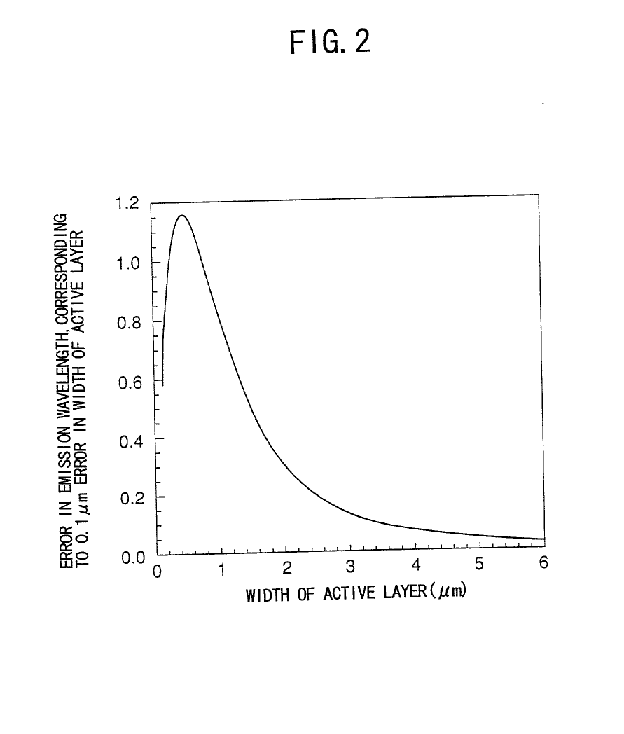

Generally, it is understood that at least a gain difference, 0.15, expressed in a standard boding coefficient, is necessary between a main mode and a subordinate mode for obtaining a single mode emission in the DFB laser diode. The coupling coefficient providing the gain difference (0.15) for the fundamental mode is shown as a broken line in FIG. 5B. As long as a coupling coefficient of a higher-order mode, for instance, a coupling coefficient of the first-order mode does not exceed a value on the broken line shown in FIG. 5B, laser emission in the first-order mode does not occur. A value of the coupling coefficient of the first-order mode exceeds a value of the broken line at an active layer width of 5.4 μm. In other words, laser emission can be restrained in the higher-order transverse modes by setting a width of the active layer 23 to 5.4 μm or the less. For instance, in the DFB laser diode emitting light of the wavelength 1550 nm, laser emission in the higher-order transverse modes and an emission wavelength error of the DFB laser diode caused by a manufacturing error described with reference to FIG. 2 can be effectively restrained, by setting a width of the active layer 23 larger than the cut-off width of the higher-order (first-order) mode in a range less than or equal to 5.4 μm.

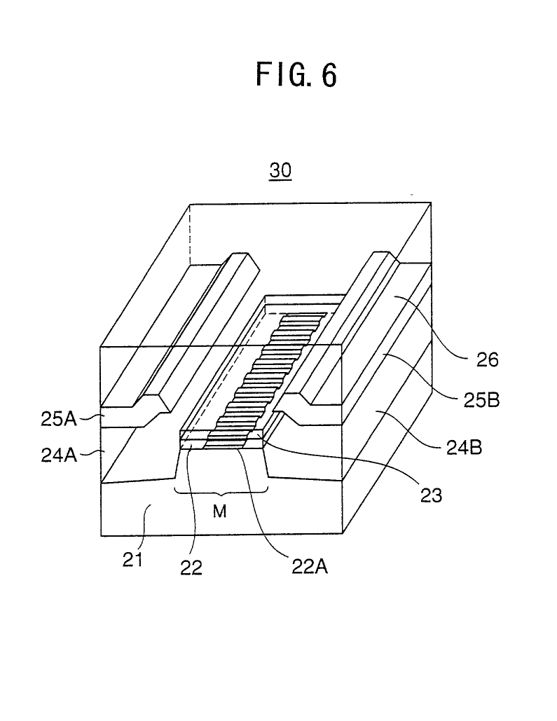

FIG. 6 is a squint diagram showing a structure of a DFB laser diode 30, according to a second embodiment of the present invention. FIG. 6 is similar to FIG. 3A. A unit shown in FIG. 6 that has been described with reference to FIG. 3A has a same unit number shown in FIG. 3A, and its description will be omitted in this embodiment.

As shown in FIG. 6, the optical waveguide layer 22 and the active layer 23 are formed on the mesa structure M to have the same width as the mesa structure M. However, the diffraction grating 22A is formed in the optical waveguide layer 22 to actually have a smaller width than the active layer 23 or the optical waveguide layer 22. In other words, the diffraction grating 22A is formed only in a center area of the active layer 23. Additionally, the active layer 23 is formed to have a width equal to or larger than 4.0 μm that is larger than the cut-off width of 1.6 μm of a higher-order transverse mode. A width of the diffraction grating 22A is set so that a standard coupling coefficient of the higher-order transverse mode is smaller than a standard coupling coefficient of the of-axis fundamental mode by 0.15 or more. The standard coupling coefficient is equal to a multiplication of a coupling coefficient and a length of an optical resonator. In the second embodiment, the width of the diffraction grating 22A is set less than or equal to the cut-off width of 1.6 μm of the higher-order transverse mode.

The boding coefficient of the DFB laser diode 30 is smaller than the previous embodiment since the diffraction grating 22A is formed only in the center area of the active layer 23 where the light intensity distribution in the higher-order transverse mode is the minimum, as shown in FIGS. 4A and 4B. Accordingly, in the DFB laser diode 30 according to the second embodiment, an emission threshold of the higher-order transverse mode is larger than that of the previous embodiment. In other words, in the DFB laser diode 30, laser emission in the higher-order modes can be restrained similarly as the previous embodiment. Additionally, an emission wavelength error cased by a manufacturing error can be effectively restrained by increasing the width of the active layer 23 than the cut-off width (the mode cut-off width). Meanwhile, the light energy in the fundamental transverse mode is concentrated in the center of the active layer 23, as shown in FIG. 4A, and, thus, a problem in which an emission threshold of the fundamental mode increases, does not occur.

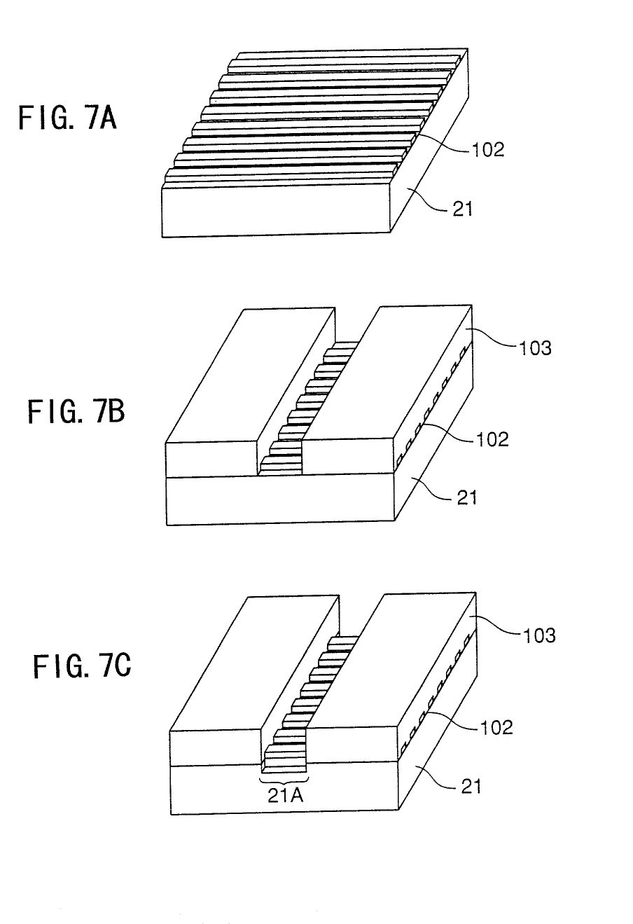

A description will now be given of manufacturing process of the DFB laser diode 30, with reference to FIGS. 7A, 7B, 7C, 8A, 8B, 8C, 9A and 9B.

At first, a resist diffraction pattern 102 having a 242 nm cycle is formed on the top of the n-type InP substrate 21 by a holographic exposure method, as shown in FIG. 7A. Additionally, as shown in FIG. 7B, a negative resist pattern 103 is formed on the top of a structure shown in FIG. 7A so that a surface of the InP substrate 21 having the resist diffraction pattern 102 on its top is exposed in an axial direction of the DFB laser diode 30 approximately for a 1.5 μm width.

Next, as shown in FIG. 7C, utilizing the resist diffraction pattern 102 and the negative resist pattern 103 as masks, the surface of the InP substrate 21 is etched for about a 30 nm depth by a dry etching method using a C₂H₆ gas as an etching gas. Consequently, a diffraction grating 21A is formed on the surface of the InP substrate 21, the diffraction grating 21A having the 242 nm cycle and the 30 nm depth.

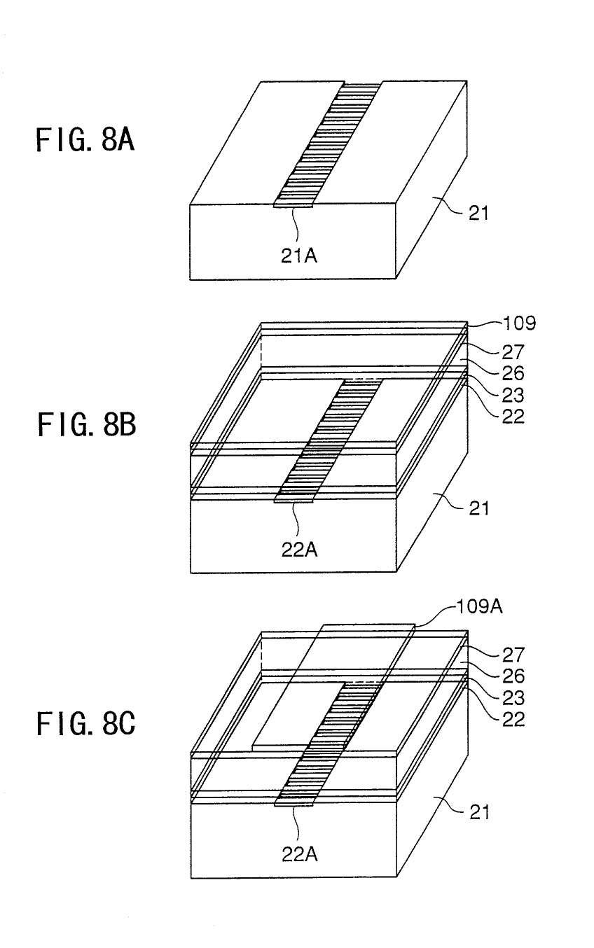

Subsequently, the resist diffraction pattern 102 and the negative resist pattern 103 are removed from the top of the InP substrate 21, as shown in FIG. 8A. An n-type GaInAsP layer having a band-gap wavelength of 1.1-1.3 μm is accumulated on the top of a structure shown in FIG. 8A approximately for 120 nm by an MOVPE method. The GaInAsP layer fulfills ditches between the InP substrate 21 and the diffraction grating 21A. Consequently, the diffraction grating 22A is formed in the GaInAsP optical waveguide layer 22, as shown in FIG. 8B. Additionally, the non-dope GaInAsP active layer 23 having a band-gap wavelength of 1.55 μm is accumulated on the top of the optical waveguide layer 22 approximately for 120 nm by the MOVPE method. On the top of the active layer 23, the p-type InP cladding layer 26 is accumulated approximately for 300 nm by the MOVPE method. Furthermore, the p-type GaInAsP cap layer 27 having a band-gap wavelength of 1.3 μm is accumulated on the top of the cladding layer 26 for 20 nm. A SiO₂ film 109 is then accumulated on the top of the cap layer 27 approximately for 300 nm.

By patterning the SiO₂ film 109 by use of a photo-lithography, an SiO₂ pattern 109A having a width of 4.0 μm is formed so that the diffraction grating 22A is located at the center of the SiO₂ pattern 109A when the diffraction grating 22A is seen from the top of the substrate 21, as shown in FIG. 8C.

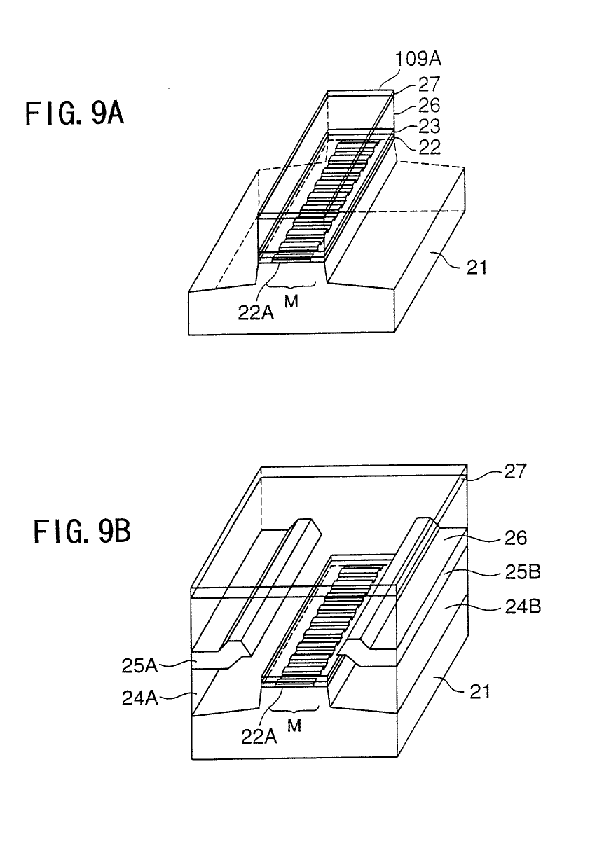

Furthermore, the mesa structure M is created by using the SiO₂ pattern 109A as a mask, and by patterning a part of the cap layer 27, the cladding layer 26, the active layer 23, the optical waveguide layer 22 and the substrate 21 by a dry etching method utilizing a C₂H₆/H₂ mixture gas. The mesa structure M created as described above exists in an axial direction of the DFB laser diode 30, and includes the diffraction grating 22A at its center, as shown in FIG. 9A.

The buried layers 24A and 24B are formed by accumulating p-type InP layers on the top of a structure shown in FIG. 9A by the MOVPE method with the SiO₂ pattern 109A remained on the top of the cap layer 27. Additionally, the current blocking layers 25A and 25B are formed respectively on the top of the buried layers 24A and 24B by accumulating n-type InP layers by the MOVPE method. Furthermore, by accumulating a p-type InP layer and a p-type GaInAsP layer on the top of the current blocking layers 25A and 25B consecutively so that the p-type InP layer and the p-type GaInAsP layer are connected to the p-type InP cladding layer 26 and the p-type GaInAsP cap layer 27, respectively. Subsequently, the SiO₂ pattern 109A is removed, and the SiO₂ film 28 is evenly accumulated on the top of the cap layer 27. The opening part 28A is patterned in the SiO₂ film 28. Finally, the upper electrode 29 and the lower electrode 30 are accumulated respectively on the top of the SiO₂ film 28 and the bottom surface of the InP substrate 21.

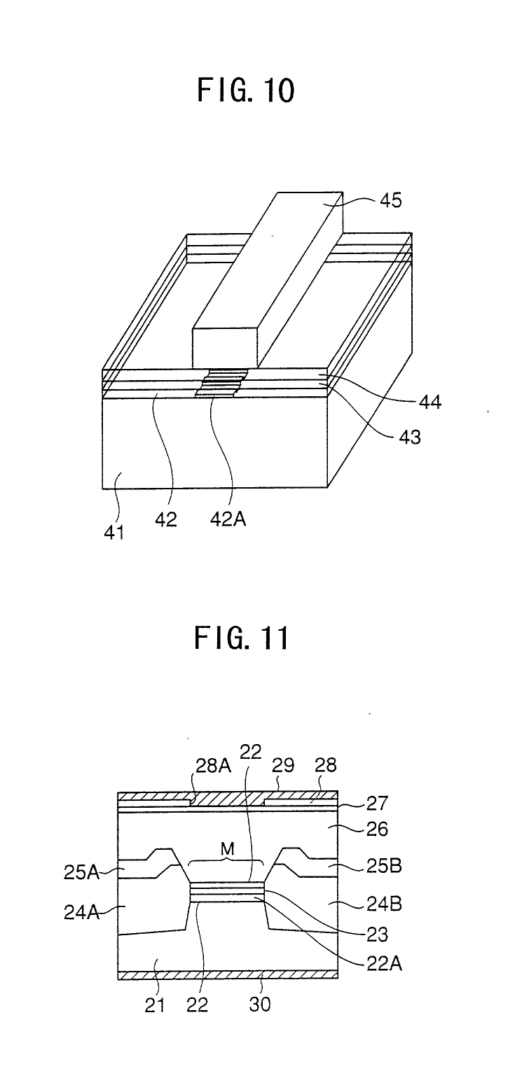

FIG. 10 is a squint diagram showing a ridge waveguide DFB laser diode 40, according to a third embodiment of the present invention. The laser diode 40 shown in FIG. 10 is formed on the top of an n-type InP substrate 41. An n-type GaInAsP optical waveguide layer 42 having a band-gap wavelength of 1.1-1.3 μm is formed on the top of the InP substrate 41 approximately for 120 nm. A diffraction grating 42A having a 30 nm depth and a 242 nm cycle is formed to exist in an axial direction of the laser diode 40 in the optical waveguide layer 42. A non-dope GaInAsP active layer 43 having a band-gap wavelength of 1.55 μm is formed on the top of the optical waveguide layer 42 approximately for 120 nm. It should be noted that the diffraction grating 42A is formed so as to have a width at which a standard coupling coefficient of a higher-order transverse mode is smaller than a standard coupling coefficient of a fundamental transverse mode by 0.15 or more. In the third embodiment, the width of the diffraction grating 42A is set less than or equal to 2.0 μm, that is, a cut-off with of a higher-order transverse mode.

Subsequently, a p-type InP cladding layer 44 is formed on the top of the active layer 43. A p-type InP ridge structure 45 is formed on the top of the cladding layer 44 so that the ridge structure exists in the axial direction of the ridge waveguide DFB laser diode 40. Additionally, an upper electrode not shown in the figures is formed on the top of the ridge structure 45 through a cap layer. A lower electrode not shown in the figures is formed on a bottom surface of the InP substrate 41.

Since the active layer 43 covers the entire substrate 41 in the DFB laser diode 40 according to the third embodiment, a difference between a measured emission wavelength and a designed emission wavelength does not occur, the difference being caused by diverse active layer widths created in a manufacturing process. Additionally, the width of the diffraction grating 42A is set so that the standard coupling coefficient of the higher-order transverse mode is smaller than the standard boding coefficient of the fundamental transverse mode by 0.15 or more, and, thus, emission in the higher-order transverse mode can be effectively restrained.

It should be noted that the active layers 23 or 43 may have a multiple quantum well (MQW) structure in the above-described embodiments.

As shown in FIG. 11, the optical waveguide layer 22 can be formed on the upper and lower sides of the active layer 23 in the DFB laser diode 20 shown in FIGS. 3A and 3B or in the DFB laser diode 30 shown in FIG. 6. Additionally, the buried layers 24A and 24B, or the current blocking layers 25A and 25B may be made of high-resistance semiconductor layers doped by a deep-impurity element such as Fe. The other components shown in FIG. 11 are the same as those of the previous embodiments, and, thus, a description will be omitted of the components.

Each of the above-described DFB laser diodes is a device including a GaInAsP semiconductor structure formed on an InP substrate. However, a GaAlInAs semiconductor structure may be substituted for the GaInAsP semiconductor structure. Additionally, the present invention is not limited to the InP substrate. For instance, the present invention can be applied to a DFB laser diode formed on a GaAs substrate.

According to the present invention, by setting a width of an active layer larger than a cut-off width of a higher-order transverse mode in a distributed feedback (DFB) laser diode, a unevenness in an emission wavelength caused by a unevenness in the active layer can be minimized. Additionally, a laser diode can be produced efficiently, the laser diode emitting light of a wavelength equal to an emission wavelength required in a wavelength division multiplex (WDM) optical communication technology.

The above description is provided in order to enable any person skilled in the art to make and use the invention and sets forth the best mode contemplated by the inventors of carrying out the invention.

The present invention is not limited to the specially disclosed embodiments and variations, and modifications may be made without departing from the scope and spirit of the invention.

The present application is based on Japanese Priority Application No. 2000-166321, filed on Jun. 2, 2000, the entire contents of which are hereby incorporated by reference.

What is claimed is:

1. A distributed feedback laser diode, comprising:
a substrate having a first conduction type;
a mesa structure having a projecting part thereof extended in an axial direction on said substrate, and forming a lower cladding layer;
an active layer formed on said projecting part, and having a width thereof wider than a cut-off width of a higher-order transverse mode formed in said active layer;
a diffraction grating optically combined with said active layer on said projecting part;
an upper cladding layer formed on said active layer, and having a second conduction type;
a first electrode electrically connected to said upper cladding layer; and
a second electrode electrically connected to said substrate.

2. The distributed feedback laser diode as claimed in claim 1, wherein the width of said diffraction grating is equal to the width of said active layer.

3. The distributed feedback laser diode as claimed in claim 1, wherein the width of said diffraction grating is less than the width of said active layer.

4. The distributed feedback laser diode as claimed in claim 1, further comprising a buried layer formed on both sides of said mesa structure on said substrate, and having a same band gap as said substrate.

5. The distributed feedback laser diode as claimed in claim 1, further comprising an optical waveguide layer adjacent to said active layer, and being optically combined with said active layer.

6. The distributed feedback laser diode as claimed in claim 5, wherein said optical waveguide layer is formed at least on one of an upper side or a lower side of said active layer.

7. A ridge waveguide distributed feedback laser diode, comprising:
a substrate having a first conduction type, and forming a lower cladding layer;
an active layer formed on said substrate, and having a width thereof less than or equal to a cut-off width of a higher-order transverse mode formed in said active layer;
an upper cladding layer formed on said active layer, and having a second conduction type;
a ridge area extended in an axial direction on said active layer, and having the second conduction type;
a first electrode electrically connected to said ridge area;
a second electrode electrically connected to said substrate; and
a diffraction grating extended in the axial direction, and being optically combined with said active layer.

8. The ridge waveguide distributed feedback laser diode as claimed in claim 7, further comprising an optical waveguide layer adjacent to said active layer, and being optically combined with said active layer, wherein said diffraction grating is formed in said optical waveguide layer.

9. The ridge waveguide distributed feedback laser diode as claimed in claim 8, wherein said optical waveguide layer is formed at least on one of an upper side or a lower side of said active layer.
